(19) United States
(12) Patent Application Publication
(10) Pub. No.: US 2026/0082868 A1
(43) Pub. Date: Mar. 19, 2026

(54) STITCHING DEFECT REDUCTION USING GAS CLUSTER BEAM

(71) Applicant: TEL Manufacturing and Engineering of America, Inc., Chaska, MN (US)

(72) Inventors: Eric Chih-Fang Liu, Albany, NY (US); Akiteru Ko, Albany, NY (US)

(21) Appl. No.: 18/887,968

(22) Filed: Sep. 17, 2024

(51) Int. Cl. H01L 21/66; H01L 21/263; H01L 21/265; H01L 21/4763; H01L 21/48

(52) U.S. Cl. CPC H10P 74/232; H10P 30/224; H10P 50/20; H10P 95/00; H10W 70/092

(57) ABSTRACT

A method of processing a substrate includes providing a substrate including a pattern of lines extending in a first direction, and reducing stitching defects by removing material from the pattern of lines using a gas cluster beam. The pattern of lines includes a first subset of lines stitched to a second subset of lines in a stitching region that includes the stitching defects. The gas cluster beam includes an azimuthal component substantially parallel to the first direction. The stitching defects may be further reduced using an additional gas cluster beam in the opposite and substantially parallel to the first direction. The method may further include exposing a first region and a second region of a photosensitive layer of the substrate to different structured actinic radiation, and forming the pattern of lines on the substrate by developing the first region and the second region.

### TECHNICAL FIELD

The present invention relates generally to semiconductor fabrication, and, in particular embodiments, to systems and methods for reducing stitching defects between stitched features using a gas cluster beam (GCB).

### BACKGROUND

The formation of microscale and nanoscale structures within a workpiece, such as within an integrated circuit (e.g., semiconductor fabrication), involves a series of processing techniques that include forming, patterning, and removing various layers of material on a substrate. Lithography processes enable the transfer of patterns onto a substrate, and include photolithography processes that use structured actinic radiation (e.g., light of a specific wavelength or narrow range of wavelengths) to pattern a layer of photosensitive material (photoresist) on the substrate. During the exposure process, the actinic radiation causes a change in the chemical structure of the photoresist that makes it more susceptible (positive tone) or less susceptible (negative tone) to being removed during a subsequent development process. When the exposed photoresist layer is developed, desired regions of the photoresist are removed leaving the pattern behind on the substrate.

The various types of photolithography can be categorized by the wavelength of the actinic radiation as well as other attributes of the exposure process, such as the medium through which the radiation propagates (gas, liquid, vacuum, etc.), the numerical aperture of the lens, and others. Among other things, these attributes affect the resolution capabilities of the photolithography process. For example, ultraviolet (UV) lithography processes, such as i-line lithography, use wavelengths in the ultraviolet range (e.g., 365 nm), deep ultraviolet (DUV) lithography processes use wavelengths in the range of about 190 nm to about 250 nm, while extreme ultraviolet (EUV) lithography processes use even shorter wavelengths, such as 13.5 nm wavelength. As the wavelength decreases, the achievable feature size also decreases (i.e., improved resolution).

Changing the propagation medium (such as from air to liquid as in immersion lithography) can further decrease the attainable feature size. The numerical aperture of the projection lens can also be increased to improve the resolution of the lithography process for any wavelength. For example, since the diffraction limit of a lithography process is inversely proportional to the numerical aperture, increasing the numerical aperture is desirable to lower the diffraction limit allowing better resolution, such as in EUV lithography processes. However, higher numerical apertures also affect other aspects of the photolithography process, such as the maximum achievable exposure field size (i.e., the size of the exposed pattern on a substrate relative to the mask size). Specifically, various factors of higher numerical aperture systems, such as increased lens complexity/size and uniformity challenges can decrease the maximum exposure field.

To counteract the smaller exposure field, the mask size may be increased. However, this can be prohibitively expensive, requiring extensive changes to equipment and processes. Alternatively, multiple regions may be exposed on the same substrate (e.g., more than one exposure in a single die, for example). The regions where the exposure fields connect are often referred to as stitching regions. Yet, precise alignment of exposure fields can be difficult, leading to stitching defects, such as undesirable extra material or misplaced material in the stitching region. Further, even with precise alignment stitching defects cannot be entirely avoided in many cases due to the need for some overlap between the exposure fields (e.g., to ensure that the patterns connect to one another). Therefore, systems and methods for reducing stitching defects are desirable.

### SUMMARY

In accordance with an embodiment of the invention, a method of processing a substrate includes providing a substrate including a pattern of lines extending in a first direction, and reducing stitching defects by removing material from the pattern of lines using a gas cluster beam. The pattern of lines includes a first subset of lines stitched to a second subset of lines in a stitching region that includes the stitching defects. The gas cluster beam includes an azimuthal component substantially parallel to the first direction.

In accordance with another embodiment of the invention, a method of processing a substrate includes exposing a first region of a photosensitive layer of a substrate to structured actinic radiation, exposing a second region of the photosensitive layer to structured actinic radiation after exposing the first region, forming a pattern of lines on the substrate by developing the first region and the second region, and reducing stitching defects by removing material from the pattern of lines using a gas cluster ion beam. The pattern of lines extends in a first direction and includes a first subset of lines in the first region and a second subset of lines in the second region. The first subset of lines is stitched to the second subset of lines in a stitching region that includes the stitching defects. The gas cluster beam includes an azimuthal component substantially parallel to the first direction.

In accordance with still another embodiment of the invention, a method of processing a substrate includes providing a substrate including a pattern of lines extending in a first direction, reducing stitching defects by removing material from excess material on sidewalls of the pattern of lines using a gas cluster beam, and further reducing the stitching defects in the stitching region by removing material from the excess material on the sidewalls using an additional gas cluster beam. The pattern of lines includes a first subset of lines stitched to a second subset of lines in a stitching region that includes the stitching defects. The stitching defects include the excess material on the sidewalls. The gas cluster beam includes an azimuthal component substantially parallel to the first direction. The additional gas cluster beam includes an azimuthal component substantially opposite of and parallel to the first direction.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example photolithography system that includes a photomask through which two fields on a substrate are separately exposed in accordance to embodiments of the invention;

FIG. 2 schematically illustrates an example photolithography system that includes a photomask that is used to form a pattern of lines on a substrate using two separate exposure fields in accordance with embodiments of the invention;

FIG. 3 schematically illustrates an example process of reducing stitching defects in a stitching region of a pattern of lines extending in a longitudinal direction using a gas cluster beam (GCB) that includes an azimuthal component substantially parallel to the longitudinal direction where the stitching defects include excessive longitudinal overlap between stitched lines in accordance with embodiments of the invention;

FIG. 4 schematically illustrates an example process of reducing stitching defects in a stitching region of a pattern of lines extending in a longitudinal direction using a GCB that includes an azimuthal component substantially parallel to the longitudinal direction where the stitching defects include insufficient longitudinal overlap between stitched lines in accordance with embodiments of the invention;

FIG. 5 schematically illustrates an example process of reducing stitching defects in a stitching region of a pattern of lines extending in a longitudinal direction using a GCB that includes an azimuthal component substantially parallel to the longitudinal direction where the stitching defects include lateral misalignment between stitched lines in accordance with embodiments of the invention;

FIG. 6 schematically illustrates a three-dimensional trimetric view of an example process of reducing stitching defects in a stitching region of a pattern of lines extending in a longitudinal direction using a GCB that includes an azimuthal component substantially parallel to the longitudinal direction in accordance with an embodiment of the invention;

FIG. 7 schematically illustrates an example GCB system that includes a processing chamber within which stitching defects in a stitching region of a pattern of lines extending in a longitudinal direction on a substrate may be reduced using a GCB that includes an azimuthal component substantially parallel to the longitudinal direction in accordance with embodiments of the invention;

FIG. 8 illustrates an example method of processing a substrate that includes reducing stitching defects using a GCB in accordance with embodiments of the invention; and

FIG. 9 illustrates another example method of processing a substrate that includes reducing defects using a GCB in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

As photolithography techniques evolve to accommodate the shrinking feature size, the scaling of the exposure field (i.e., the difference between the mask size, and the exposure field) continues to decrease. That is, the exposure continues to get smaller relative to the mask size. Making new masks is costly and increasing the mask size may increase complexity as well as cost. Moreover, die sizes come in many different sizes and have also been increasing in size over time. The numerical aperture of the projection lens is one of many factors that contribute to decreased scaling of the exposure field.

The maximum achievable exposure field size for a given mask size is already small (e.g., smaller than an individual die at times). Yet current EUV projection lenses also have relatively low numerical apertures, such as in the range of 0.33. Higher numerical aperture (NA) EUV projection lenses are being developed, targeting 0.55 and even higher. These High-NA EUV projection lenses will have an even smaller achievable exposure field size. Therefore, while stitching defects between features formed with separate exposure fields may be problem for any type of photolithography, the problem may be especially important for High-NA EUV photolithography processes. Unfortunately, current techniques to reduce stitching defects lack the fine control necessary to avoid damaging the non-defect regions of the stitched features.

In accordance with embodiments herein described, the invention proposes a method of processing a substrate that includes reducing stitching defects in a stitching region using a GCB (gas cluster beam) that is directed along the length of the stitched features. Specifically, the substrate includes a pattern of features (e.g., lines) with at least two feature subsets that have been formed separately with the intention of “stitching” the features together to form continuous features. However, the formation of the stitched features results in defects in the stitching region (e.g., from misalignment of exposure fields during lithography processes). For example, in the stitching region (i.e., an area at and around where the features connect), some or all of the features may overlap more than desired, less than desired, or even not overlap.

In one embodiment, the substrate includes a pattern of lines extending in a longitudinal direction (i.e., the longitudinal direction is parallel to the length of the line features). The pattern of lines includes a first subset of lines stitched to a second subset of lines in a stitching region that has stitching defects. The method includes reducing the stitching defects in the stitching region by removing material from the pattern of lines using a GCB (gas cluster beam), such as a gas cluster ion beam (GCIB), that has an azimuthal component substantially parallel to the first direction. That is, the GCB may be at any angle with the substrate (e.g., from 0 to 90 degrees relative to the normal direction of the plane of the substrate), but the projection of the beam onto the plane of the substrate is substantially parallel to the length of the lines (the first direction). In some embodiments, an additional GCB substantially may also be used that is opposite of and parallel to the longitudinal direction.

In various embodiments, the method of processing the substrate includes forming the pattern of lines on the substrate using two exposures of a photosensitive layer (i.e., two exposure fields, which may use the same photomask). For example, a first exposure may use structured actinic radiation to expose a first region of the photosensitive layer while a separate, second exposure may use structured actinic radiation (i.e., different from the first exposure, such as through a different reticle and the same photomask, a different exposure performed after the first exposure, etc.) to expose a second region of the photosensitive layer. The pattern of lines may then be formed by developing the first region and the second region. Optionally, the pattern of lines formed by developing the exposed regions may be transferred to an underlying layer by etching the underlying layer using the developed photosensitive layer as an etch mask.

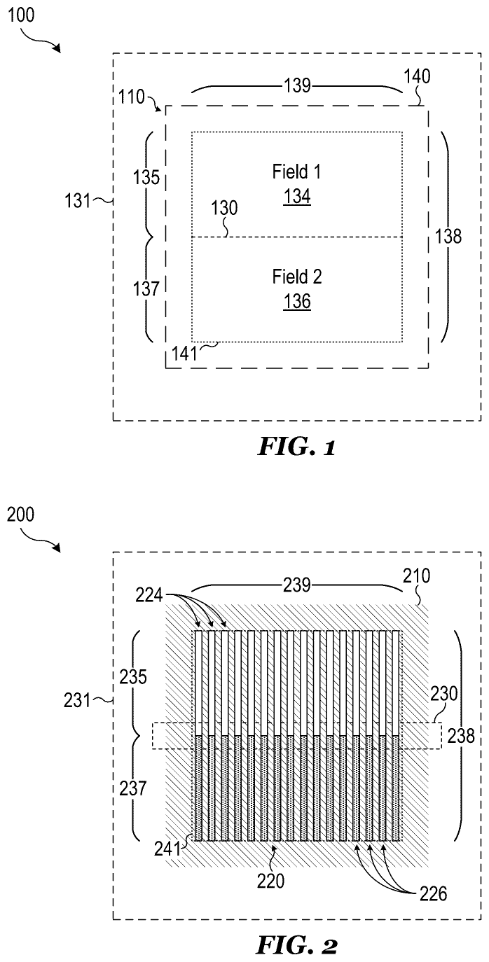

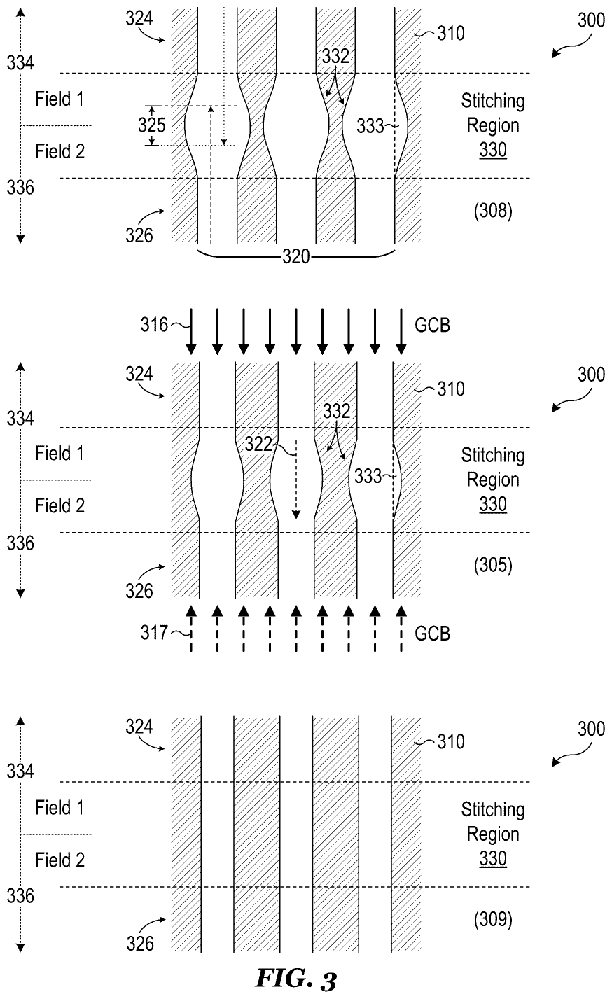

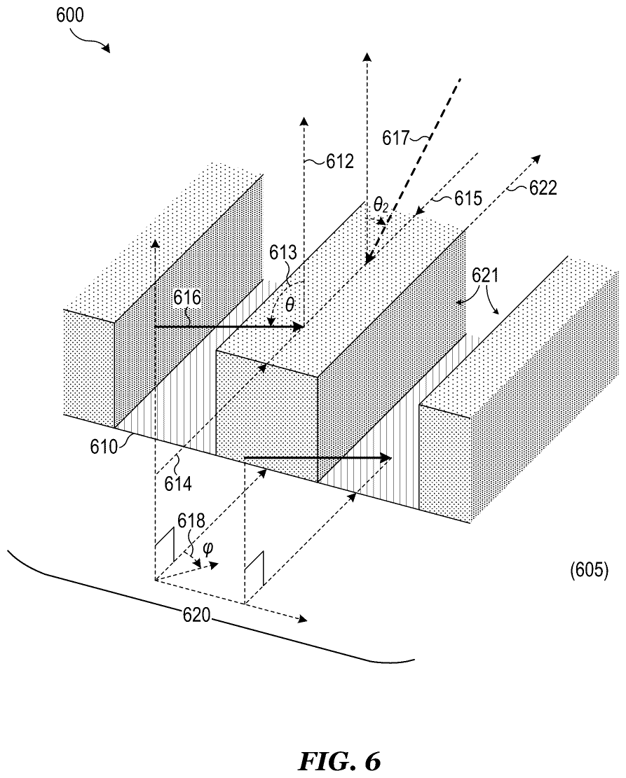

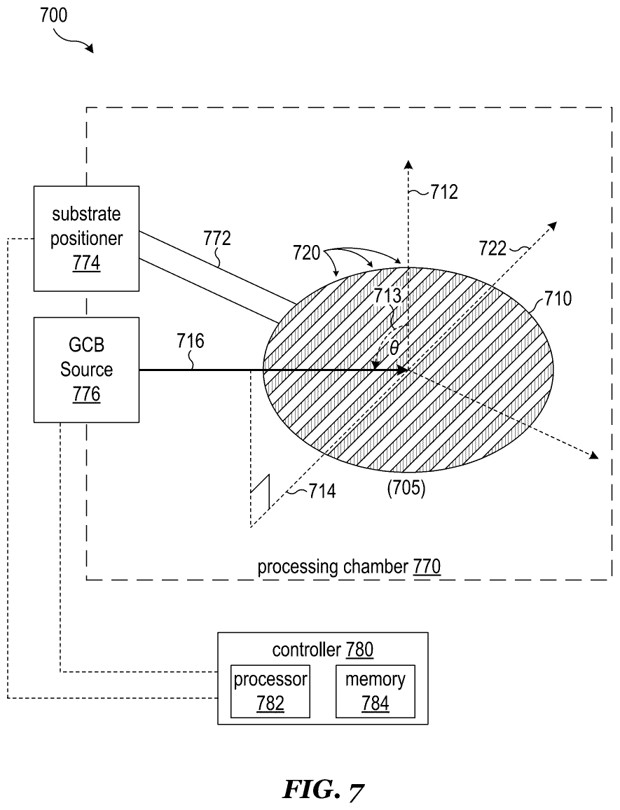

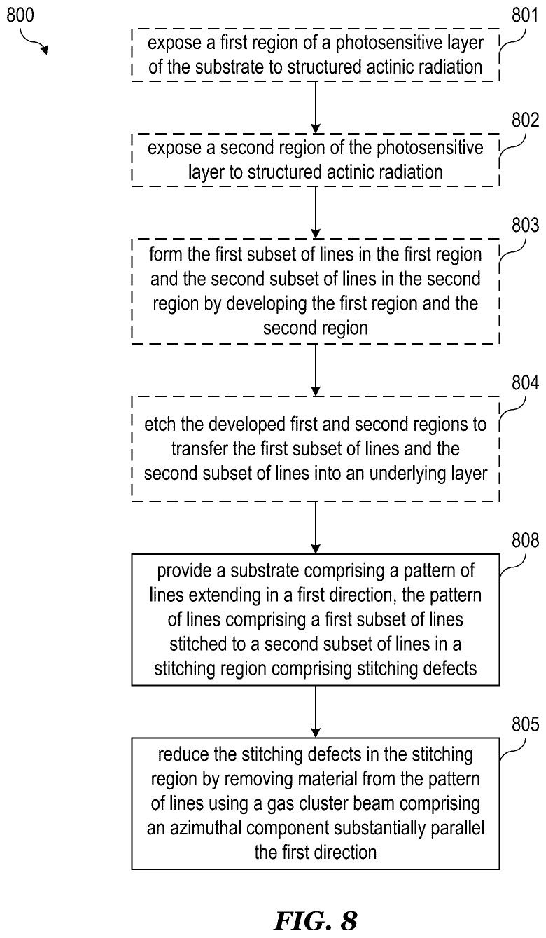

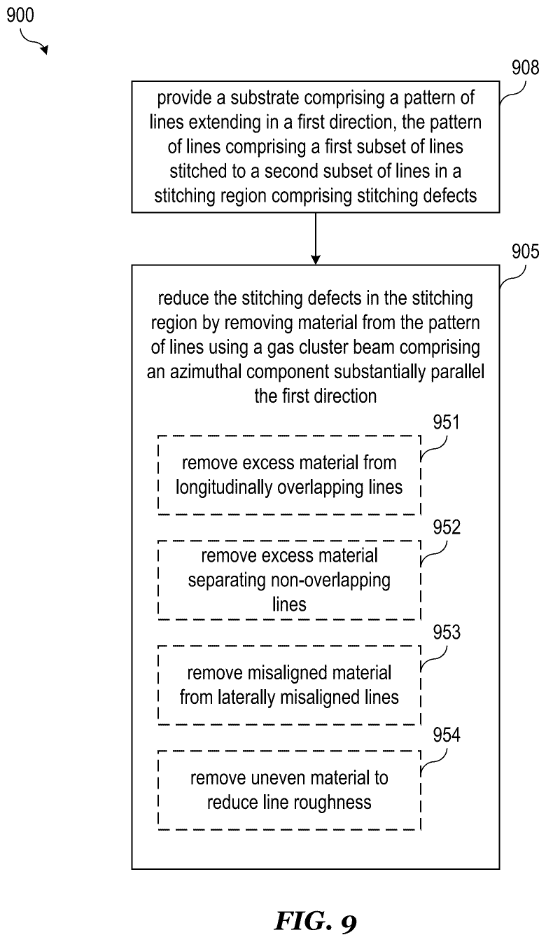

Embodiments provided below describe various systems and methods for reducing stitching defects between stitched features using a GCB, and in particular embodiments, to systems and methods for reducing the stitching defects using a GCB that includes an azimuthal component that is substantially parallel to the longitudinal extension of the stitched features. The following description describes the embodiments. FIGS. 1 and 2 and two are used to describe example photolithography systems that use separate exposure fields stitched together. Three example processes of reducing stitching defects with three different broad categories of defects are described using FIG. 3-5. Another example process of reducing stitching defects is described using FIG. 6. An example GCB system is described using FIG. 7 and two example methods of processing a substrate that includes reducing stitching defects are described using FIGS. 8 and 9.

FIG. 1 schematically illustrates an example photolithography system that includes a photomask through which two fields on a substrate are separately exposed in accordance to embodiments of the invention.

Referring to FIG. 1, a photolithography system 100 includes a substrate 110 that has a first exposure field 134 and a second exposure field 136. The first exposure field 134 and the second exposure field 136 are spatially separate and directly adjacent to one another so that the fields connect in a stitching region 130. A photomask 131 may be used to expose one or both of the first exposure field 134 and the second exposure field 136 (e.g., expose a photosensitive layer 140) as part of a lithography process that forms features on the substrate 110. For example, a pattern of lines may be formed on the substrate 110 using the lithography process and the photomask 131 may define a subset of lines that are projected separately to both the first exposure field 134 and the second exposure field 136 and stitched together in the stitching region 130.

Each of the exposure fields is smaller than the area that the complete pattern is intended to cover (e.g., smaller than the die size, for example) which leads to the desire to stitch the fields together in the stitching region 130 form the complete pattern. Any desirable size and shape is possible for the first exposure field 134, the second exposure field 136, and the photomask 131 (or multiple photomask in embodiments that use separate masks). However, in various embodiments, the first exposure field 134 and the second exposure field 136 have a similar size and shape, such as when a single photomask is used for both exposures. In some cases, such as when a higher numerical aperture is used during the exposure process, one dimension of the exposure fields may be scaled differently than the other dimension.

In this specific example, the first exposure field 134 has a first longitudinal dimension 135 and the second exposure field 136 has a second longitudinal dimension 137 that together form a total longitudinal dimension 138 of a combined region 141. Meanwhile, the first exposure field 134 and the second exposure field 136 both have a lateral dimension 139 equal to the lateral dimension of the combined region 141, although of course this does not have to be the case. For example, more than two exposure fields may be used to cover the combined region 141 in some embodiments, such as additional exposure fields in the longitudinal direction, as well as the lateral direction, if desired. Further configurations will be apparent to those of skill in the art in view of this disclosure.

As discussed in the foregoing, the stitching region 130 may include stitching defects between features of the first exposure field 134 and features of the second exposure field 136. The features formed by exposing the fields have connecting sidewalls that run in the longitudinal direction, a specific example of which is a pattern of lines (illustrated and described using subsequent figures). Because the stitched features include longitudinal sidewalls in the stitching region 130, one or more GCBs (gas cluster beams) that have directional component substantially in the longitudinal direction may be used to reduce stitching defects related to the stitching of the longitudinal sidewalls.

FIG. 2 schematically illustrates an example photolithography system that includes a photomask that is used to form a pattern of lines on a substrate using two separate exposure fields in accordance with embodiments of the invention. The photolithography system of FIG. 2 may be a specific implementation of other photolithography systems described herein such as the photolithography system of FIG. 1, for example. Similarly labeled elements may be as previously described.

Referring to FIG. 2, a photolithography system 200 includes a substrate 210 that has a pattern of lines 220 formed thereon. It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system. For example, the substrate 210 may be a specific example of the substrate 110 where the features are a pattern of lines and a photosensitive layer has been exposed and developed to form the pattern of lines 220.

A first subset of lines 224 has been formed using a first exposure field while a second subset of lines 226 has been formed using a second exposure field. The first and second exposure fields together form a combined region 241. As before, each of the fields (and therefore each of the first subset of lines 224 and the second subset of lines 226) are smaller than the complete pattern. Continuing the example dimensions of FIG. 1, the first subset of lines 224 are formed in an exposure field having a first longitudinal dimension 235 whereas the second subset of lines 226 are formed in an exposure field having a second longitudinal dimension 237 that together form a total longitudinal dimension 238 of the combined region 241. The exposure fields share a lateral dimension 239 equal to the lateral dimension of the combined region 241. It should be noted that there is no requirement that the respective subsets of lines cover an entire exposure region, are all stitched to another line, or that line features are the only type of feature in the exposure region. Variations to the example shown here will be apparent to those of skill in the art relying on the present disclosure.

A photomask 231 may have been used to expose both of the first and second exposure fields of the combined region 241 during separate exposures (e.g., through different reticles or with different alignment). A development process was then used to form the pattern of lines 220. The first subset of lines 224 and the second subset of lines 226 are stitched together in a stitching region 230. Here, the stitching region 230 is depicted as an idealized case where ends of the lines are stitched together precisely with not defects to form continuous lines.

In practice, stitching defects (not shown) will be present in the stitching region 230 due to alignment variability, among other factors. Indeed, although the type and extent of the stitching defects may vary depending on the specific details of a given implementation, the stitching defects are unavoidable due to the desire to ensure reliable connection between the stitched features. As feature sizes become smaller (e.g., fine pitch line patterns formed using High-NA EUV lithography, for example) stitching defects become both untenable and unavoidable. However, the pattern of lines 220 extends in the longitudinal direction creating longitudinal sidewalls that stitched together in the stitching region 230. Therefore, one or more GCBs having a directional component substantially in the longitudinal direction may be used to reduce stitching defects related to the stitching of the longitudinal sidewalls. FIG. 3-5 are used to describe three example stitching defects that may be reduced using such beams in more detail.

FIG. 3 schematically illustrates an example process of reducing stitching defects in a stitching region of a pattern of lines extending in a longitudinal direction using a GCB that includes an azimuthal component substantially parallel to the longitudinal direction where the stitching defects include excessive longitudinal overlap between stitched lines in accordance with embodiments of the invention. The process of FIG. 3 may be performed on a pattern on lines formed on a substrate using a photolithography system described herein such as the photolithography system of FIG. 1, for example. Similarly labeled elements may be as previously described.

Referring to FIG. 3, a process 300 includes a substrate 310 in an initial state 308 where a pattern of lines 320 that extend in a longitudinal direction 322 have been formed using two exposure fields. Specifically, a first subset of lines 324 has been formed in a first exposure field 334 and a second subset of lines 326 has been formed in a second exposure field 336. The first subset of lines 324 and the second subset of lines 326 are stitched together in the longitudinal direction 322 in a stitching region 330.

In this specific example, the exposure of the first subset of lines 324 and the second subset of lines 326 overlap longitudinally in an overlap region 325. That is, the relative positions of the exposure of the first exposure field 334 and the second exposure field 336 are such that the overlap region 325 receives a higher exposure dose resulting in stitching defects 332 manifesting as bulges in the stitching region 330 in this example. The overexposure in the stitching region 330 causes excess material 333 of the pattern of lines 320 to be present. It should be noted that the correlation of the actual location of the respective exposures to the presence of the bulge (i.e., the degree of exposure overlap) may vary depending on the specific details of the lithography process. For example, the actual exposure may overlap in some cases while in other cases the actual exposure region may not overlap, but stitching defects taking the form of bulges may still form because the exposure regions are still too close.

In a defect reduction step 305 of the process 300, a GCB 316 is applied to the pattern of lines 320 on the substrate 310 to reduce the stitching defects 332 by removing some or all of the excess material 333. The GCB 316 has a directional component that is substantially parallel to the longitudinal direction 322. For example, although the substrate 310 is here depicted from an overhead view as a 2D plane, the GCB 316 may have any desired angle with the substrate 310 other than normal to the plane of the substrate 310 (a beam normal to the substrate 310 would not have a component in the longitudinal direction 322). Therefore, recognizing that in practice the GCB 316 is being applied in a 3D space, the azimuthal component of the GCB 316 is substantially parallel to the longitudinal direction 322 while the angle that the GCB 316 makes with the normal of the substrate 310 (e.g., the tilt angle of the substrate in practice) may take any desired value greater than 0 degrees up to and including 90 degrees.

As may suspected, the illustration of the stitching defects 332 as bulges is schematic. Therefore, while the depiction may be fairly accurate in some applications, the stitching defects 332 may have other shapes resulting in excess material having other shapes due to overexposure of line patterns that are laterally aligned, but longitudinally misaligned. For example, the transition from the line sidewall to the stitching defects 332 may be less smooth or vary significantly from line to line. Moreover, the pattern of lines 320 may have general line roughness (not shown) that may also be improved using the GCB 316 in some embodiments.

The GCB 316 may be applied in any suitable manner, including a global exposure where the GCB 316 simultaneously exposes the entire substrate 310 as well as varying degrees of local exposure where the GCB 316 is scanned over the substrate 310. For example, the GCB 316 may simultaneously an entire die region and be scanned to process all of the die regions on the GCB 316 (e.g., a wafer). The cross-section of the GCB 316 may also be smaller than a die region and be scanned within each die region. Of course, the pattern of lines 320 may cover only certain regions of the substrate 310. Accordingly, the process 300 may scan the substrate 310 so that the GCB 316 is not applied to regions without the pattern of lines 320.

In some cases, the cross-section of the GCB 316 and control over the GCB 316 (e.g., using a shutter) may be such that the GCB 316 may be turned off when directed at locations not in the stitching region 330 and turned on while directed at the stitching region 330. This may have the advantage of avoiding or reducing the removal of material outside of the stitching region 330 region (i.e., from parts of the pattern of lines 320 that do not have stitching defects). Moreover, in some embodiments, a combination may be used where regions outside the stitching region 330 are exposed to the GCB 316 (e.g., to smooth line roughness) while the stitching region 330 receives a higher dose of the GCB 316 to remove the stitching defects 332.

The GCB 316 may be any suitable type of gas cluster beam. That is, a source gas may be processed to form gas clusters (e.g., gas clusters may be formed by condensation induced by adiabatic expansion of compressed gas into a vacuum). The gas clusters may have any desired mixture of species, including ions, neutrals, radicals, plasma effluents, and others. The gas clusters may be accelerated in the direction of the substrate 310 using suitable techniques, which may differ depending on the specific composition details of the gas clusters. Upon reaching surfaces of the substrate 310, the gas clusters may interact with the materials both physically and chemically. For example, at impact, the clusters may disintegrate and deliver kinetic energy that may dislodge regions of the excess material 333. In one embodiment, the GCB 316 is a GCIB (gas cluster ion beam). In the specific case of a GCIB, the gas clusters may be ionized to produce ions, such as through collisions with energetic electrons. The ionized clusters may be accelerated by a voltage differential towards the substrate 310.

The mechanism of removing the excess material 333 may be related to the azimuthal component of the GCB 316 being in the longitudinal direction 322. That is, the gas cluster species may physically dislodge material from the excess material 333 from surfaces that are at least partially facing the longitudinal direction 322. For example, the bulges of the stitching defects 332 have surfaces that allow the GCB 316 to collide with sufficient energy to remove the excess material 333 resulting to a processed state 309 where some or all (as depicted) of the excess material 333 has been removed. Advantageously, the GCB 316 may remove less or no material from surfaces of the pattern of lines 320 that do not face the GCB 316 (e.g., sidewalls of the pattern of lines 320).

In some embodiments, it may be desirable to also apply an optional additional GCB 317 with a component substantially in the opposite azimuthal direction as the GCB 316. Although there is no requirement that the optional additional GCB 317 share any particular parameters other than the opposite nature of the azimuthal component, the optional additional GCB 317 may be applied at a similar angle with the normal of the substrate 310 and with similar beam properties (as the stitching defects 332 may be substantially symmetric).

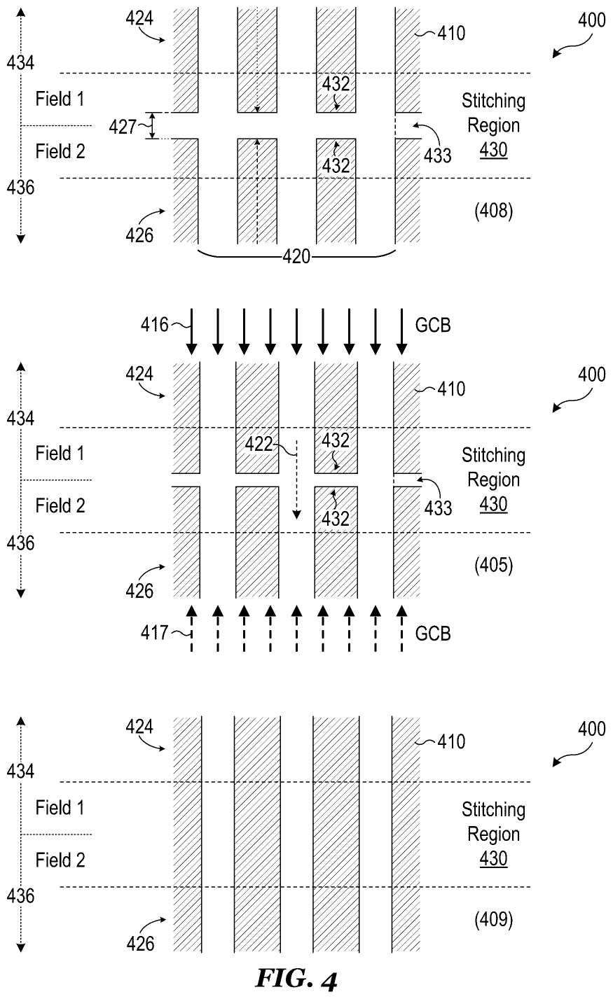

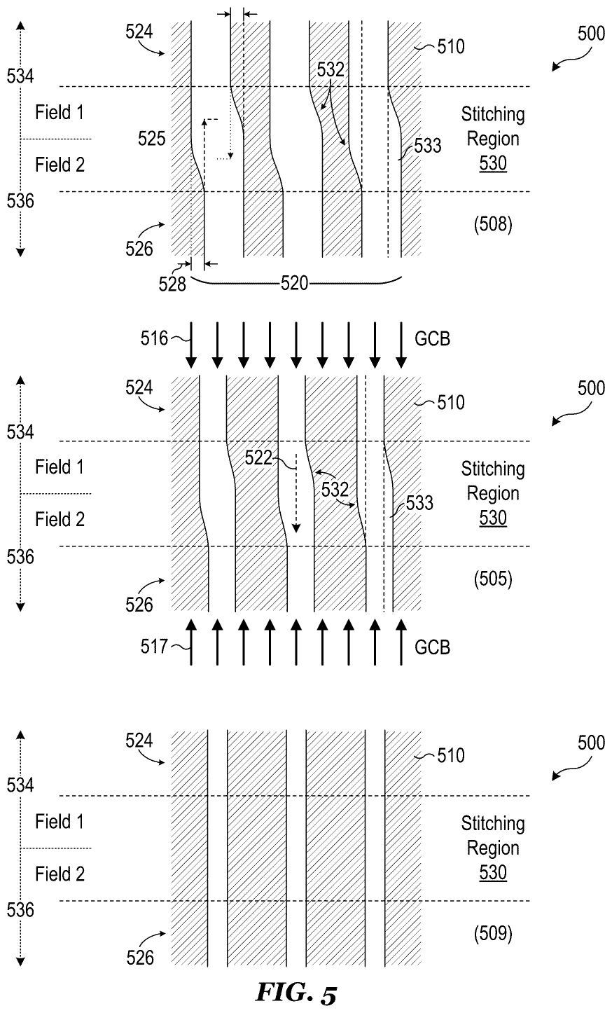

FIG. 4 schematically illustrates an example process of reducing stitching defects in a stitching region of a pattern of lines extending in a longitudinal direction using a GCB that includes an azimuthal component substantially parallel to the longitudinal direction where the stitching defects include insufficient longitudinal overlap between stitched lines in accordance with embodiments of the invention. The process of FIG. 4 may be a specific example of other processes described herein such as the process of FIG. 3, for example. Similarly labeled elements may be as previously described.

Referring to FIG. 4, a process 400 includes a substrate 410 in an initial state 408 where a pattern of lines 420 that extend in a longitudinal direction 422 have been formed using two exposure fields. Specifically, a first subset of lines 424 has been formed in a first exposure field 434 and a second subset of lines 426 has been formed in a second exposure field 436. The first subset of lines 424 and the second subset of lines 426 are stitched together in the longitudinal direction 422 in a stitching region 430.

In this specific example, the exposure of the first subset of lines 424 and the second subset of lines 426 do not overlap longitudinally in non-overlap region 427. For example, the photoresist layer used to form the pattern of lines 420 (whether directly or with a subsequent etch) may be a positive tone resist and the first exposure field 434 and the second exposure field 436 may be longitudinally misaligned so that excess material 433 remains between some or all of the first subset of lines 424 and the second subset of lines 426 as stitching defects 432. In contrast to the example of FIG. 3, the stitching defects 432 may result from an underexposure in the stitching region 430 (as opposed to an overexposure). It should be noted that more than one type of stitching defect may exist on the same substrate, such as when there is rotational misalignment, resulting in overexposure in stitching regions of parts of the substrate and underexposure in stitching regions of other parts of the substrate. In some cases, multiple types of stitching defects may be present in the same stitching region.

As before, in a defect reduction step 405 of the process 400, a GCB 416 is applied to the pattern of lines 420 on the substrate 410 to reduce the stitching defects 432 by removing some or all of the excess material 433. In various embodiments, an optional additional GCB 417 may also be applied. The mechanism of removing the excess material 433 may be related to the azimuthal component of the GCB 416 being in the longitudinal direction 422. That is, the gas cluster species may physically dislodge material from the excess material 433 from surfaces that are at least partially facing the longitudinal direction 422. In this specific example, the surfaces of the excess material 433 are substantially perpendicular to the GCB 416 and the optional additional GCB 417, when included. The GCB 416 may remove material until the substrate 410 is in a processed state 409 where each of the first subset of lines 424 and the second subset of lines 426 reliably connected to one another.

FIG. 5 schematically illustrates an example process of reducing stitching defects in a stitching region of a pattern of lines extending in a longitudinal direction using a GCB that includes an azimuthal component substantially parallel to the longitudinal direction where the stitching defects include lateral misalignment between stitched lines in accordance with embodiments of the invention. The process of FIG. 5 may be a specific example of other processes described herein such as the process of FIG. 3, for example. Similarly labeled elements may be as previously described.

Referring to FIG. 5, a process 500 includes a substrate 510 in an initial state 508 where a pattern of lines 520 that extend in a longitudinal direction 522 have been formed using two exposure fields. Specifically, a first subset of lines 524 has been formed in a first exposure field 534 and a second subset of lines 526 has been formed in a second exposure field 536. The first subset of lines 524 and the second subset of lines 526 are stitched together in the longitudinal direction 522 in a stitching region 530. In this specific example, the exposure of the first subset of lines 524 and the second subset of lines 526 have a lateral misalignment in a lateral misalignment region 528. The lateral misalignment results in excess material 533 on one side of the first subset of lines 524 and on the opposite side of the second subset of lines 526. Of course, the lateral misalignment may be in addition to other defect types, as already described.

In a defect reduction step 505 of the process 500, both a GCB 516 and an optional additional GCB 517 are applied to the pattern of lines 520 on the substrate 510 to reduce the stitching defects 532 by removing some or all of the excess material 533. As discussed in the foregoing, the mechanism of removing the excess material 533 may be related to the azimuthal component of the GCB 516 being in the longitudinal direction 522. Since only some of the surfaces of the excess material 533 are facing the GCB 516, the additional GCB 517 is also applied to remove the excess material 533 from the remaining surfaces. Once the substrate 510 has been processed from both directions with the GCB 516 and the additional GCB 517, respectively, the substrate 510 is in a processed state 509 where some or all of the excess material 533 has been removed.

FIG. 6 illustrates schematically illustrates a three-dimensional trimetric view of an example process of reducing stitching defects in a stitching region of a pattern of lines extending in a longitudinal direction using a GCB that includes an azimuthal component substantially parallel to the longitudinal direction in accordance with an embodiment of the invention. The process of FIG. 6 may be a specific example of other processes described herein such as the process of FIG. 3, for example. Similarly labeled elements may be as previously described.

Referring to FIG. 6, a process 600, which may be similar to any of the previously described processes, is shown during a defect reduction step 605 where a GCB 616 is applied to a pattern of lines 620 formed on a substrate 610. As shown, the GCB 616 is applied with an azimuthal component 614 that is substantially parallel to a longitudinal direction 622 of sidewalls 621 of the pattern of lines 620. If the azimuthal component 614 were not substantially parallel, an azimuthal angle 618 would be nonzero, which may be undesirable because additional sidewall material (e.g., significant material that is not part of the stitching defects) may be removed by the GCB 616. The GCB 616 is also applied with a tilt angle 613 relative to a normal direction 612 of the substrate 610, which may be selected as any desired angle greater than zero up to and including 90 degrees. As before, an optional additional GCB 617 with an additional azimuthal component 615 may also be applied in some embodiments.

FIG. 7 schematically illustrates an example gas cluster beam system that includes a processing chamber within which stitching defects in a stitching region of a pattern of lines extending in a longitudinal direction on a substrate may be reduced using a GCB that includes an azimuthal component substantially parallel to the longitudinal direction in accordance with embodiments of the invention. The gas cluster beam system of FIG. 7 may be used to perform processes and methods described herein such as the process of FIG. 3, for example. Similarly labeled elements may be as previously described.

Referring to FIG. 7, a GCB system 700 is shown during a defect reduction step 705. The GCB system 700 includes a processing chamber 770 within which a GCB source 776 is used to apply a GCB 716 to a pattern of lines 720 formed on a substrate 710 and extending in a longitudinal direction 722. The GCB 716 is applied at a tilt angle 713 relative to a normal direction 712 of the substrate 710 and with an azimuthal component 714 substantially parallel to the longitudinal direction 722. Although the GCB 716 may be applied to the entire substrate 710 in some embodiments, in this specific example a substrate support 772 is mechanically coupled to a substrate positioner 774 that is used to manipulate the position of the substrate 710 allowing the desired tilt angle 713 to be maintained and the substrate 710 to be moved to scan the GCB 716 over the desired regions of the substrate 710 (e.g., in a raster pattern).

A controller 780 is operatively coupled to the various components of the GCB system 700, including the substrate positioner 774 and the GCB source 776. The controller 780 includes one or more processors 782 and at least one memory 784 (i.e., a non-transitory computer-readable medium) that stores a program including instructions that, when executed by the one or more processors 781, perform the defect reduction steps described herein.

FIG. 8 illustrates an example method of processing a substrate that includes reducing stitching defects using a GCB in accordance with embodiments of the invention. The method of FIG. 8 may be combined with other methods, incorporate the processes described herein, and be performed using the systems and apparatuses as described herein. For example, the method of FIG. 8 may be combined with any of the embodiments of FIG. 1-7 and 9. Although shown in a logical order, the arrangement and numbering of the steps of FIG. 8 are not intended to be limited. The method steps of FIG. 8 may be performed in any suitable order or concurrently with one another as may be apparent to a person of skill in the art. Previously labeled elements may be as previously described.

Referring to FIG. 8, a method 800 of processing a substrate includes a defect reduction step 805 that is performed on the substrate as it is provided in an initial state 808. Specifically, the substrate includes a pattern of lines that extend in a first direction (i.e., a longitudinal direction) in the initial state 808. The pattern of lines includes a first subset of lines stitched to a second subset of lines in a stitching region and the stitching region has stitching defects. During the defect reduction step 805, the stitching defects in the stitching region are reduced by removing material from the pattern of lines using a GCB (e.g., a GCIB) with an azimuthal component substantially parallel to the first direction.

The stitching region may include various stitching defects or combinations of stitching defects. For example, certain stitching defects may result in excess material on sidewalls of the pattern lines, which may be removed using the GCB. At times, one or more of the lines may not connect, and excess material separating the lines may be removed to connect the lines. Additionally, the lines may be generally rough, including uneven material that has an undesirable level of line roughness. The uneven surfaces may provide target surfaces that may be impacted and removed by the GCB so that the surfaces are smoothed and line roughness of the pattern of lines is reduced.

Additionally, as previously described, an additional GCB may also be used further reduce stitching defects. The additional GCB may have an azimuthal component substantially opposite of and parallel to the first direction. The amount of material that is removed from upper surfaces of the pattern of lines and the substrate during the defect reduction step 805 may be related to the tilt angle at which the GCB (and the additional GCB, when included) are applied to the substrate. For example, a shallow tilt angle may allow the GCB to impact the upper surface more head on, increasing the rate of material removal from the upper surfaces. Therefore, in some applications, a higher tilt angle may be desirable. In various embodiments, the tilt angle of the substrate relative to the GCB is greater than about 60 degrees.

In some embodiments, the method 800 may also include the preparation of the substrate to arrive at the initial state 808. For example, a first exposure step 801 may be included in the method 800 during which a first region of a photosensitive layer of the substrate is exposed to structured actinic radiation (e.g., as part of a high-NA EUV exposure process). Different structured actinic radiation may then be used to expose a second region of the photosensitive layer in a second exposure step 802 (e.g., after the first exposure step 801, but that may also be simultaneous with the first exposure step 801, such as by using splitting optics/different light sources and different reticles, for example).

The first subset of lines may then be formed in the first region along with the second subset of lines in the second region by developing the first region and the second region during a development step 803. In various embodiments, the first region and the second region are within a single die region of the substrate, which may motivate the stitching technique. While the development step 803 of both regions happens simultaneously in many embodiments, the regions could be separately developed, such as if the first region is developed between the first exposure step 801 and the second exposure step 802, if desired.

The development step 803 may directly form the pattern of lines from a photosensitive layer. In this case, the pattern of lines is made of the photosensitive material and excess photosensitive material is removed from the stitching region with the GCB. Alternatively, an optional etching step 804 may also be included after the development step to etch the developed first and second regions and transfer the first subset of lines and the second subset of lines into an underlying layer. For this case, the pattern of lines is made of the underlying material, which is the material that is removed from the stitching region with the GCB.

FIG. 9 illustrates another example method of processing a substrate that includes reducing stitching defects using a GCB in accordance with embodiments of the invention. The method of FIG. 9 may be combined with other methods, incorporate the processes described herein, and be performed using the systems and apparatuses as described herein. For example, the method of FIG. 9 may be combined with any of the embodiments of FIG. 1-8. Although shown in a logical order, the arrangement and numbering of the steps of FIG. 9 are not intended to be limited. The method steps of FIG. 9 may be performed in any suitable order or concurrently with one another as may be apparent to a person of skill in the art. Previously labeled elements may be as previously described.

Referring to FIG. 9, a method 900 of processing a substrate includes a defect reduction step 905 that is performed on the substrate as it is provided in an initial state 908. Specifically, as before, the substrate includes a pattern of lines that extend in a first direction (i.e., a longitudinal direction) in the initial state 908. The pattern of lines includes a first subset of lines stitched to a second subset of lines in a stitching region and the stitching region has stitching defects. During the defect reduction step 905, the stitching defects in the stitching region are reduced by removing material from the pattern of lines using a GCB (e.g., a GCIB) with an azimuthal component substantially parallel to the first direction.

The reduction of stitching defects may include one or more specific type of defect. For example, the defect reduction step 905 may include one or more of a longitudinal overlap correction 951 that removes excess material from longitudinally overlapping lines, a non-overlap correction 952 that removes excess material separating non-overlapping lines, a lateral misalignment correction 953 that removes misaligned material from laterally misaligned lines, and a roughness reduction 954 that removes uneven material on sidewalls of the lines to reduce line roughness.

Example embodiments of the invention are summarized here. Other embodiments can also be understood from the entirety of the specification as well as the claims filed herein.
Example 1. A method of processing a substrate, the method including: providing a substrate including a pattern of lines extending in a first direction, the pattern of lines including a first subset of lines stitched to a second subset of lines in a stitching region including stitching defects; and reducing the stitching defects in the stitching region by removing material from the pattern of lines using a gas cluster beam including an azimuthal component substantially parallel to the first direction.
Example 2. The method of example 1, further including: exposing a first region of a photosensitive layer of the substrate to structured actinic radiation; exposing a second region of the photosensitive layer to structured actinic radiation after exposing the first region; and forming the first subset of lines in the first region and the second subset of lines in the second region by developing the first region and the second region.
Example 3. The method of example 2, where forming the first subset of lines and the second subset of lines further includes: etching the developed first and second regions to transfer the first subset of lines and the second subset of lines into an underlying layer.
Example 4. The method of one of examples 2 and 3, where exposing the first region and exposing the second region each include a high numerical aperture extreme ultraviolet exposure process.
Example 5. The method of one of examples 2 to 4, where the first region and the second region are within a single die region of the substrate.
Example 6. The method of one of examples 1 to 5, where the gas cluster beam is a gas cluster ion beam.
Example 7. The method of one of examples 1 to 6, where the stitching defects include excess material on sidewalls of the pattern of lines in the stitching region, and where reducing the stitching defects includes removing material from the excess material on the sidewalls.
Example 8. The method of one of examples 1 to 7, where the stitching defects include excess material separating the first subset of lines from the second subset of lines in the stitching region, and where reducing the stitching defects includes removing the excess material to connect the first subset of lines to the second subset of lines.
Example 9. The method of one of examples 1 to 8, where the stitching defects include lateral misalignment between the first subset of lines and the second subset of lines in the stitching region, and where reducing the stitching defects includes removing misaligned material from sidewalls of the pattern of lines.
Example 10. The method of one of examples 1 to 9, further including: reducing line roughness of the pattern of lines using the gas cluster beam.
Example 11. The method of one of examples 1 to 10, further including: further reducing the stitching defects in the stitching region by removing material from the pattern of lines using an additional gas cluster beam including an azimuthal component substantially opposite of and parallel to the first direction.
Example 12. The method of one of examples 1 to 11, where a tilt angle of the substrate relative to the gas cluster beam is greater than about 60 degrees.
Example 13. A method of processing a substrate, the method including: exposing a first region of a photosensitive layer of a substrate to structured actinic radiation; exposing a second region of the photosensitive layer to structured actinic radiation after exposing the first region; forming a pattern of lines on the substrate by developing the first region and the second region, the pattern of lines extending in a first direction and including a first subset of lines in the first region and a second subset of lines in the second region, the first subset of lines being stitched to the second subset of lines in a stitching region including stitching defects; and reducing the stitching defects in the stitching region by removing material from the pattern of lines using a gas cluster ion beam including an azimuthal component substantially parallel to the first direction.
Example 14. The method of example 13, where the stitching defects include excess material on sidewalls of the pattern of lines in the stitching region, and where reducing the stitching defects includes removing material from the excess material on the sidewalls.
Example 15. The method of one of examples 13 and 14, where the stitching defects include excess material separating the first subset of lines from the second subset of lines in the stitching region, and where reducing the stitching defects includes removing the excess material to connect the first subset of lines to the second subset of lines.
Example 16. The method of one of examples 13 to 15, where the stitching defects include lateral misalignment between the first subset of lines and the second subset of lines in the stitching region, and where reducing the stitching defects includes removing misaligned material from sidewalls of the pattern of lines.
Example 17. A method of processing a substrate, the method including: providing a substrate including a pattern of lines extending in a first direction, the pattern of lines including a first subset of lines stitched to a second subset of lines in a stitching region including stitching defects, the stitching defects including excess material on sidewalls of the pattern of lines; reducing the stitching defects in the stitching region by removing material from the excess material on the sidewalls using a gas cluster beam including an azimuthal component substantially parallel to the first direction; and further reducing the stitching defects in the stitching region by removing material from the excess material on the sidewalls using an additional gas cluster beam including an azimuthal component substantially opposite of and parallel to the first direction.
Example 18. The method of example 17, where the stitching defects include lateral misalignment between the first subset of lines and the second subset of lines in the stitching region, and where reducing the stitching defects includes removing misaligned material from the sidewalls of the pattern of lines.
Example 19. The method of one of examples 17 and 18, further including: exposing a first region of a photosensitive layer of the substrate to structured actinic radiation; exposing a second region of the photosensitive layer to structured actinic radiation after exposing the first region; and forming the first subset of lines in the first region and the second subset of lines in the second region by developing the first region and the second region.
Example 20. The method of one of examples 17 to 19, where a tilt angle of the substrate relative to the gas cluster beam is greater than about 60 degrees.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
providing a substrate comprising a pattern of lines extending in a first direction, the pattern of lines comprising a first subset of lines stitched to a second subset of lines in a stitching region comprising stitching defects; and
reducing the stitching defects in the stitching region by removing material from the pattern of lines using a gas cluster beam comprising an azimuthal component substantially parallel to the first direction.

2. The method of claim 1, further comprising:
exposing a first region of a photosensitive layer of the substrate to structured actinic radiation;
exposing a second region of the photosensitive layer to structured actinic radiation after exposing the first region; and
forming the first subset of lines in the first region and the second subset of lines in the second region by developing the first region and the second region.

3. The method of claim 2, wherein forming the first subset of lines and the second subset of lines further comprises:
etching the developed first and second regions to transfer the first subset of lines and the second subset of lines into an underlying layer.

4. The method of claim 2, wherein exposing the first region and exposing the second region each comprise a high numerical aperture extreme ultraviolet exposure process.

5. The method of claim 2, wherein the first region and the second region are within a single die region of the substrate.

6. The method of claim 1, wherein the gas cluster beam is a gas cluster ion beam.

7. The method of claim 1, wherein the stitching defects comprise excess material on sidewalls of the pattern of lines in the stitching region, and wherein reducing the stitching defects comprises removing material from the excess material on the sidewalls.

8. The method of claim 1, wherein the stitching defects comprise excess material separating the first subset of lines from the second subset of lines in the stitching region, and wherein reducing the stitching defects comprises removing the excess material to connect the first subset of lines to the second subset of lines.

9. The method of claim 1, wherein the stitching defects comprise lateral misalignment between the first subset of lines and the second subset of lines in the stitching region, and wherein reducing the stitching defects comprises removing misaligned material from sidewalls of the pattern of lines.

10. The method of claim 1, further comprising:
reducing line roughness of the pattern of lines using the gas cluster beam.

11. The method of claim 1, further comprising:
further reducing the stitching defects in the stitching region by removing material from the pattern of lines using an additional gas cluster beam comprising an azimuthal component substantially opposite of and parallel to the first direction.

12. The method of claim 1, wherein a tilt angle of the substrate relative to the gas cluster beam is greater than about 60 degrees.

13. A method of processing a substrate, the method comprising:
exposing a first region of a photosensitive layer of a substrate to structured actinic radiation;
exposing a second region of the photosensitive layer to structured actinic radiation after exposing the first region;
forming a pattern of lines on the substrate by developing the first region and the second region, the pattern of lines extending in a first direction and comprising a first subset of lines in the first region and a second subset of lines in the second region, the first subset of lines being stitched to the second subset of lines in a stitching region comprising stitching defects; and
reducing the stitching defects in the stitching region by removing material from the pattern of lines using a gas cluster ion beam comprising an azimuthal component substantially parallel to the first direction.

14. The method of claim 13, wherein the stitching defects comprise excess material on sidewalls of the pattern of lines in the stitching region, and wherein reducing the stitching defects comprises removing material from the excess material on the sidewalls.

15. The method of claim 13, wherein the stitching defects comprise excess material separating the first subset of lines from the second subset of lines in the stitching region, and wherein reducing the stitching defects comprises removing the excess material to connect the first subset of lines to the second subset of lines.

16. The method of claim 13, wherein the stitching defects comprise lateral misalignment between the first subset of lines and the second subset of lines in the stitching region, and wherein reducing the stitching defects comprises removing misaligned material from sidewalls of the pattern of lines.

17. A method of processing a substrate, the method comprising:
providing a substrate comprising a pattern of lines extending in a first direction, the pattern of lines comprising a first subset of lines stitched to a second subset of lines in a stitching region comprising stitching defects, the stitching defects comprising excess material on sidewalls of the pattern of lines;
reducing the stitching defects in the stitching region by removing material from the excess material on the sidewalls using a gas cluster beam comprising an azimuthal component substantially parallel to the first direction; and
further reducing the stitching defects in the stitching region by removing material from the excess material on the sidewalls using an additional gas cluster beam comprising an azimuthal component substantially opposite of and parallel to the first direction.

18. The method of claim 17, wherein the stitching defects comprise lateral misalignment between the first subset of lines and the second subset of lines in the stitching region, and wherein reducing the stitching defects comprises removing misaligned material from the sidewalls of the pattern of lines.

19. The method of claim 17, further comprising:
exposing a first region of a photosensitive layer of the substrate to structured actinic radiation;
exposing a second region of the photosensitive layer to structured actinic radiation after exposing the first region; and
forming the first subset of lines in the first region and the second subset of lines in the second region by developing the first region and the second region.

20. The method of claim 17, wherein a tilt angle of the substrate relative to the gas cluster beam is greater than about 60 degrees.
